(19) United States
(12) Patent Application Publication
(10) Pub. No.: US 2019/0207073 A1
(43) Pub. Date: Jul. 4, 2019

(54) THERMOELECTRIC ARTICLE AND COMPOSITE MATERIAL FOR A THERMOELECTRIC CONVERSION DEVICE AND PROCESS FOR PRODUCING A THERMOELECTRIC ARTICLE

(71) Applicant: Vacuumschmelze GmbH & Co. KG, Hanau (DE)

(72) Inventors: Alberto BRACCHI, Hanau (DE); Michael MÜLLER, Wörth (DE)

(73) Assignee: Vacuumschmelze GmbH & Co. KG, Hanau (DE)

(21) Appl. No.: 16/314,383

(22) PCT Filed: Jun. 30, 2017
(86) PCT No.: PCT/EP2017/025190

§ 371 Date: Dec. 28, 2018

(30) Foreign Application Priority Data
Jun. 30, 2016 (DE) 10 2016 211 877.3

(51) Int. Cl. H01L 35/18; C22C 30/04; H01L 35/34

(52) U.S. Cl. CPC H01L 35/18; B22F 9/04; H01L 35/34; C22C 30/04

(57) ABSTRACT

A thermoelectric article and process for producing a thermoelectric article for a thermoelectric conversion device is provided. The thermoelectric article has an overall composition consisting essentially of 6 atom %≤Ti≤27 atom %, 6 atom %≤Zr≤27 atom %, 0 atom %≤Hf≤1.7 atom %, where 28 atom %≤(Ti+Zr+Hf)≤38 atom %;

28 atom %≤Sn≤38 atom %, 0 atom %≤Sb≤3 atom %, where 28 atom %≤(Sn+Sb)≤38 atom %; 0 atom %≤A≤7 atom %, 0 atom %≤B≤7 atom %, where A is Sc, Y and/or La, B is V, Nb and/or Ta and 0.15 atom %≤A+B≤7 atom %; the rest being Ni and up to 5 atom % impurities.

This application is a 371 national phase entry of PCT/EP2017/025190 filed on 30 Jun. 2017, which claims benefit of DE 10 2016 211 877.3, filed 30 Jun. 2016, the entire contents of which are incorporated herein by reference for all purposes.

### BACKGROUND

### 1. Technical Field

The invention relates to a thermoelectric article for a thermoelectric conversion device, a composite material for a thermoelectric conversion device and a process for producing a thermoelectric article for a thermoelectric conversion device. The invention relates, in particular, to thermoelectric materials based on half-Heusler compounds.

### 2. Related Art

Thermoelectric effects permit the direct conversion of thermal energy into electrical energy and vice versa. Depending on application, a distinction is made between the Seebeck effect and the Peltier effect.

The Peltier effect describes how an electrical current in a material is connected to a heat flow. The relationship between heat flow and electrical current is referred to as the Peltier coefficient. In a closed electric circuit comprising two conductors with different Peltier coefficients the heat balance at the contacts is not even and one contact heats up while the other contact cools down.

The Seebeck effect, by contrast, states that a temperature difference between two ends of a material leads to the formation of an electrical voltage proportional to that temperature difference. The ratio between the voltage and the temperature difference is referred to as the Seebeck coefficient (S).

These thermoelectric effects find technical applications in, for example, thermocouples for temperature measurement, thermoelectric modules (TE modules) for cooling/heating and in thermoelectric modules for the generation of electricity. Thermoelectric modules for cooling/heating are also referred to as Peltier modules, while modules for generating electricity are also referred to as thermoelectric generators (TEGs).

Half-Heusler compounds are intermetallic compounds with the general formula αβχ, which have an ordered cubic C1_{b} crystalline structure. A transition metal α, a transition metal β and a main-group metal χ each occupy one of three nested, face-centred, cubic sub-lattices. A fourth face-centred sub-lattice is unoccupied. If the sum of the valence electrons in this structure is 18, the compounds display a semi-conductor behaviour with an energy gap of 0 to 1 eV. As a result they are efficient thermoelectric materials particularly suitable for a mid-temperature range of approximately 400° C. to 600° C.

The efficiency of materials is described by the thermoelectric figure of merit ZT, which is defined as ZT=T S²σ/κ, where T is the absolute temperature, S the Seebeck coefficient, σ the electric conductivity and κ the heat conductivity. In addition to the ZT value, the power factor PF, calculated from PF=S²σ, is also frequently used to compare different thermoelectric materials.

Good n-type thermoelectric half-Heusler compounds are known in the system αNiSn (α=Zr, Hf, Ti). It is possible here, by means of substitutions on the various sub-lattices, to develop thermoelectric materials with high ZT values. Isoelectronic substitution on the α lattice site by Ti, Zr and Hf in order to reduce heat conductivity and doping on the Sn lattice site by means of the donor Sb in order to increase electric conductivity are disclosed in US 2010/0147352 A1 and US2005/0172994 A1, for example.

A disadvantage of αNiSn-based compounds is that a high proportion of hafnium on the α lattice site is required to reach a high ZT value. As hafnium is currently a very expensive raw material it would be desirable to reduce the Hf content.

In addition to isoelectronic substitution, US 2010/0147352 A1 and US2005/0172994 A1 also disclose the substitution of the α lattice site by acceptor or donor elements from side groups 3 (Sc, Y, La) and 5 (V, Nb, Ta) to improve the thermoelectric properties of the αNiSn system. In doing so it is important to avoid the formation of foreign phases due to too high a proportion of these elements. In general, these compounds can be described by the chemical formula AₓB_{y}α_{1-x-y}Niχ. Here A is one or more of the p-type doping acceptor elements Sc, Y and La; B is one or more of the n-type doping donor elements V, Nb, Ta; α is Ti, Zr or Hf and χ is one or both of the elements Sn and Sb.

US2005/0172994 A1 shows examples of the substitution of acceptor and donor elements without the formation of foreign phases in half-Heusler compounds with α=Ti_{0.3}Zr_{0.35}Hf_{0.35} and α=Ti_{0.5}Zr_{0.25}Hf_{0.25}. US 2010/0147352 A1, on the other hand, deals with reduced-Hf half-Heusler phases in which the proportion of Hf on the α lattice site is restricted to less than 1%. The substitution of acceptor and donor elements without the formation of foreign phases is shown in half-Heusler compounds with α=Ti and α=Zr. ZT values of up to a maximum of 0.7 have been reached in these reduced-Hf half-Heusler compounds.

### SUMMARY

The object of the invention is therefore to provide an n-type thermoelectric material in which the proportion of hafnium is reduced and which simultaneously has a high ZT value.

According to the invention a thermoelectric article for a thermoelectric conversion device is provided having an overall composition consisting essentially of
6 atom %≤Ti≤27 atom %,
6 atom %≤Zr≤27 atom %,
0 atom %≤Hf≤1.7 atom %, where 28 atom %≤(Ti+Zr+Hf)≤38 atom %;
28 atom %≤Sn≤38 atom %,
0 atom %≤Sb≤3 atom %, where 28 atom %≤(Sn+Sb)≤38 atom %;
0 atom %≤A≤7 atom %,
0 atom %≤B≤7 atom %, where A is one or more of the elements chosen from the group consisting of Sc, Y and La, B is one or more of the elements selected from the group consisting of V, Nb and Ta and 0.15 atom %≤A+B≤7 atom %;
the rest being Ni and up to 5 atom % impurities.

This overall composition achieves a half-Heusler compound containing both Ti and Zr, in particular at least 6 atom % Ti and 6 atom % Zr. One or more of the elements Ti and Zr of the half-Heusler phase can be partially replaced with Hf, the proportion of Hf in the total (Ti+Zr+Hf) on the α lattice site being ≤5 atom %. This overall composition has a low Hf content of less than 1.7 atom %, so that due to the reduced Hf content the raw material cost of the thermoelectric material is reduced, enabling the materials to be used economically for thermoelectric conversion. At the same time, the thermoelectric article has both good thermoelectric properties and a high ZT value.

The hafnium content can be provided exclusively or partially by a percentage of Hf present in the zirconium source. For example, the zirconium can comprise between 0.5 atom % and 3 atom % Hf as an accompanying element. Consequently, the overall composition is not Hf-free, though no hafnium is specifically added to the composition. If the proportion of Hf in the zirconium source is too low, the hafnium content can be increased by the use of a further, separate source of hafnium. In the manufactured thermoelectric article the hafnium can be arranged at the lattice site instead of zirconium or titanium.

The overall composition of the thermoelectric article can also be described by the formula AₓB_{y}Tiₐ₁Zrₐ₂Hfₐ₃NiSn_{c}Sb_{b}, where 0≤x≤0.2, 0≤y≤0.2. 0.005≤(x+y)≤0.2, 0.2≤a1≤0.8, 0.2≤a2≤0.8, 0≤a3≤0.05, 0.9≤(a1+a2+a3)≤1.1, 0≤b≤0.1 and 0.9≤(b+c)≤1.1. The content of elements A and B can be identical such that x=y as written above, or different such that x≠y.

Impurities refers to elements that have not been specifically added to the overall composition or that result from the manufacturing process. These impurities may contain one or more elements from the group consisting of O, C, N, Al and Fe. The maximum content of the individual elements can be O≤4 atom %, C≤1 atom %, N≤0.5 atom %, Al≤2 atom % and Fe≤2 atom %, the maximum total content of impurities being up to 5 atom %.

A thermoelectric article with an overall composition according to the invention has very good thermoelectric properties. In one embodiment the thermoelectric article has a maximum thermoelectric figure of merit ZTₘₐₓ of ≥0.8, preferably ≤0.9, where 400° C.≤Tₘₐₓ≤700° C., and/or a Seebeck coefficient S, where −350≤S≤(μV/K)−80, and/or a maximum power factor PFₘₐₓ of ≥3.5 (mW m⁻¹ K⁻²).

The thermoelectric article can have a plurality of phases such that the composition of the individual phases differs from the overall composition. In particular, the thermoelectric article can have at least 90 vol % of at least one phase with a half-Heusler structure. This half-Heusler compound can have at least 6 atom % Ti and 6 atom % Zr. The rest of the thermoelectric article may be made up of A-rich and B-rich phases. Neither the one or more A-rich phases nor the one or more B-rich phases can have a half-Heusler structure. The A-rich phases and B-rich phases can take the form of inclusions or precipitates that are present in a matrix with a half-Heusler structure. Good thermoelectric properties are provided despite these further A-rich and B-rich phases without a half-Heusler structure.

The thermoelectric article can have at least one phase with a half-Heusler structure. In some embodiments the thermoelectric article has at least two phases with a half-Heusler structure that have different compositions. The phase or phases with the half-Heusler structure can each have less than 0.2 atom % of one or both elements A and B such that these elements are predominantly present in the form of A-rich and/or B-rich precipitates. For example, 0.2 atom % is the detection limit of methods such as energy-dispersive X-ray spectroscopy (EDX).

The composition of the phases with the half-Heusler structure can be defined by the chemical formula TiₐZr₁₋ₐNiSn_{1-b}Sb_{b}, where 0≤a≤1 and 0≤b≤0.1. In some embodiments 0.2≤a≤0.8.

The invention also discloses a composite material for a thermoelectric conversion process that has a matrix having at least one phase with a half-Heusler structure based on αNiβ, α being at least one of the elements of the group consisting of Ti, Zr and Hf and β being at least one of the elements of the group consisting of Sn and Sb, the proportion of Hf in Ti+Zr+Hf being less than 5 atom %, inclusions from an A-rich phase, A being one or more of the elements selected from the group consisting of Sc, Y and La, inclusions from a B-rich phase, B being one or more of the elements selected from the group consisting of V, Nb and Ta, and a maximum thermoelectric figure of merit ZTₘₐₓ of ≤0.8, preferably 50.9.

As a result, this composite material has good thermoelectric properties despite the inclusion of additional phases alongside the half-Heusler compound or compounds.

The composition of the phases with the half-Heusler structure can be defined by the chemical formula TiₐZr₁₋ₐNiSn_{1-b}Sb_{b}, where 0≤a≤1 and 0≤b≤0.1, and in some embodiments 0.2≤a≤0.8.

In one embodiment the matrix has fewer than 0.2 atom % of one or more of the elements A and B. In some embodiments, in contrast to the matrix, however, the inclusions from an A-rich phase and the inclusions from a B-rich phase have no half-Heusler structure. The composite material can have up to 10 vol % of the A-rich phase and the B-rich phase. The composite material therefore has a half-Heusler structure with no or very few substitutions of elements A and B and good thermoelectric properties.

The composite material can have an overall composition consisting essentially of 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, where 28 atom %≤(Sn+Sb)≤38 atom %; 0 atom %≤A≤7 atom %, 0 atom %≤B≤27 atom %, where A is one or more of the elements selected from the group consisting of Sc, Y and La, B is one or more of the elements selected from the group consisting of V, Nb and Ta and 0.15 atom %≤A+B≤7; the rest being Ni and up to 5 atom % of impurities.

One or both of the elements Ti and Zr of the half-Heusler phase can be partially replaced with Hf, the proportion of Hf in the sum (Ti+Zr+Hf) being ≤5 atom %, i.e. the proportion of Hf on the lattice site of the half-Heusler phase is less than 5 atom %.

The impurities can comprise one or more of the elements of the group consisting of O, C, N, Al and Fe. The maximum content of the individual elements can be O≤4 atom %, C≤1 atom %, N≤0.5 atom %, Al≤2 atom % and Fe≤2 atom %, where the maximum total content of impurities can be up to 5 atom %.

Also disclosed is a thermoelectric module having at least one thermoelectric element made of a composite material according to one of the embodiments described above.

According to the invention, a process for producing a thermoelectric articles for a thermoelectric conversion device comprises the following. A starting material consisting essentially of 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, where 28 atom %≤(Sn+Sb)≤38 atom %, 0 atom %≤A≤7 atom %, 0 atom %≤B≤27 atom %, where A is one or more of the elements selected from the group consisting of Sc, Y and La, B is one or more of the elements selected from the group consisting of V, Nb and Ta and 0.15 atom %≤A+B≤7; the rest being Ni and up to 5 atom % of impurities is provided, melted and then hardened to form at least one block. The block is heat-treated or homogenised at a temperature of 900° C. to 1200° C. for a length of time t, where 0.5 h ≤t≤100 h, in order to produce a homogenised block. The homogenised block is crushed and milled or ground, thereby forming a powder. The powder is cold pressed, thereby forming a green body. The green body is sintered at a maximum pressure of 1 MPa and a temperature of 1000° C. to 1500° C. for 0.5 h to 24 h, thereby producing a thermoelectric article.

The impurities can comprise one or more of the elements of the group consisting of O, C, N, Al and Fe. The maximum content of the individual elements can be O≤4 atom %, C≤1 atom %, N≤0.5 atom %, Al≤2 atom % and Fe≤2 atom %, where the maximum total content of impurities can be up to 5 atom %.

In the thermoelectric element one or both of the elements Ti and Zr of the half-Heusler phase can be partially replaced with Hf, the proportion of Hf on the α lattice site of the half-Heusler phase and in the sum (Ti+Zr+Hf) being up to 5 atom %.

The molten material can be cast into a block. The block or cast block can be crushed or reduced to small pieces by a jaw crusher and/or by a disc mill or roller mill. The block can be processed into a powder is a plurality of steps. For example, the block can be reduced to a coarse powder, and then the coarse powder can be ground into a fine powder in a further milling process, the fine powder being cold pressed to form the green body. The further grinding process can be carried out using a planetary ball mill or a jet mill.

The starting material can be melted by vacuum induction melting (VIM). Vacuum induction melting is particularly advantageous for producing industrial-scale quantities of material.

The block can be homogenised in argon or in a vacuum. In one embodiment the heat treatment conditions for homogenisation are defined in greater detail with the block being homogenised at a temperature of 1050° C. to 1180° C. for a length of time t, where 16 h≤t≤36 h.

The proportion of impurities may increase as a result of the production process with the proportion of impurities in the finished article being up to 5 atom %.

In the embodiments described above the starting material, which is melted and processed into a powder, has the desired content of the elements Ti, Zr, Hf, A, B, Sn, Sb and Ni. In further embodiments the overall composition is prepared from two or more powders with different compositions.

A process for producing a thermoelectric article is provided in which at least one powder containing the elements A and/or B is mixed with a powder containing none or less than the desired proportion of these elements. The process can comprise the following. A first powder that consists essentially of 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, where 28 atom %≤(Sn+Sb)≤38 atom %; the rest being Ni and up to 5 atom % of impurities, the proportion of elements in groups A and B being less than 0.2 atom. At least one second powder is provided comprising 0 atom %≤A≤7 atom % and/or 0 atom %≤B≤7 atom %, where A is one or more of the elements selected from the group consisting of Sc, Y and La, B is one or more of the elements selected from the group consisting of V, Nb and Ta and 0.5 atom %≤A+B≤7 atom %. The first powder and the second powder are mixed together, thereby producing a starting powder. This starting powder is cold pressed to form a green body and the green body is sintered at a maximum pressure of 1 MPa at a temperature of 1000° C. to 1500° C. for 0.5 h to 24 h, thereby producing a thermoelectric article.

In addition to the elements A and/or B, the second powder can also comprise 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, where 28 atom %≤(Sn+Sb)≤38 atom %; the being Ni and up to 5 atom % of impurities. The second powder can thus have one or more phases with a half-Heusler structure.

For both production methods the green body can be sintered in a protective gas or a vacuum. The sintered thermoelectric article can also be further processed to produce at least one working component suitable for use in a thermoelectric module. For example, the sintered article can be processed to form a plurality of working components by means of sawing and/or grinding processes.

The sintered thermoelectric article produced using the two processes can have a matrix made up of at least one phase with a half-Heusler structure comprising less than 0.2 atom % of elements A and B and inclusions or precipitates of A-rich and/or B-rich phases. The sintered thermoelectric article can comprise up to 10 vol % of these A-rich and B-rich phases and still have thermoelectric properties with a maximum thermoelectric figure of merit of ZTₘₐₓ of ≥0.8, preferably ≥0.9, where 400° C.≤Tₘₐₓ≤700° C., and/or a Seebeck coefficient S, where −350≤S≤(μV/K)−80, and/or a maximum power factor PFₘₐₓ of >3.5 (mW m⁻¹ K⁻²).

### BRIEF DESCRIPTION OF THE DRAWINGS

The invention is explained in greater detail below using the drawings and examples.

FIG. 1 shows a diagram of the composition of the α lattice site in the compound αNiSn (α=Ti, Zr, Hf), the shaded region representing the region examined for α.

FIG. 2 shows a scanning electron microscope image of the microstructure of Example 1.1.

FIG. 3 shows a scanning electron microscope image of the microstructure of the material from Example 2.4.

FIG. 4 shows graphs of the thermoelectric properties of the materials from Example 3.

FIG. 5 shows a scanning electron microscope image of the microstructure of the material from Example 4.1.

FIG. 6 shows a scanning electron microscope image of the microstructure of the material from Example 2.4.

FIG. 7 shows graphs of the thermoelectric properties of the materials from Example 5.

FIG. 8 shows graphs of the thermoelectric properties of the materials from Example 6.

### DETAILED DESCRIPTION OF EXAMPLE EMBODIMENTS

A thermoelectric article having an overall composition consisting essentially of 6 atom %≤Ti≤27 atom %, 6 atom %≤Zr≤27 atom %, where 28 atom %≤(Ti+Zr)≤38 atom %; 0 atom %≤Hf≤1.7 atom %, where one or both of the elements Ti and Zr of the half-Heusler phase can be partially replaced by Hf such that 28 atom %≤(Ti+Zr+Hf)≤38 atom %, where the proportion of Hf in the sum (Ti+Zr+Hf)≤5 atom %; 28 atom %≤Sn≤38 atom %, 0 atom %≤Sb≤3 atom %, where 28 atom %≤(Sn+Sb)≤38 atom %; 0 atom %≤A≤7 atom %, 0 atom %≤B≤7 atom %, where A is one or more of the elements selected from the group consisting of Sc, Y and La, B is one or more of the elements selected from the group consisting of V, Nb and Ta and 0.15 atom %≤A+B≤7; the rest being Ni and up to 5 atom % of impurities. The thermoelectric article has a sintered, multi-phase composite structure with a matrix consisting of at least one phase with a half-Heusler structure with less than 0.2 atom % of the elements A and B and inclusions or precipitates of A-rich and/or B-rich phases embedded in the matrix.

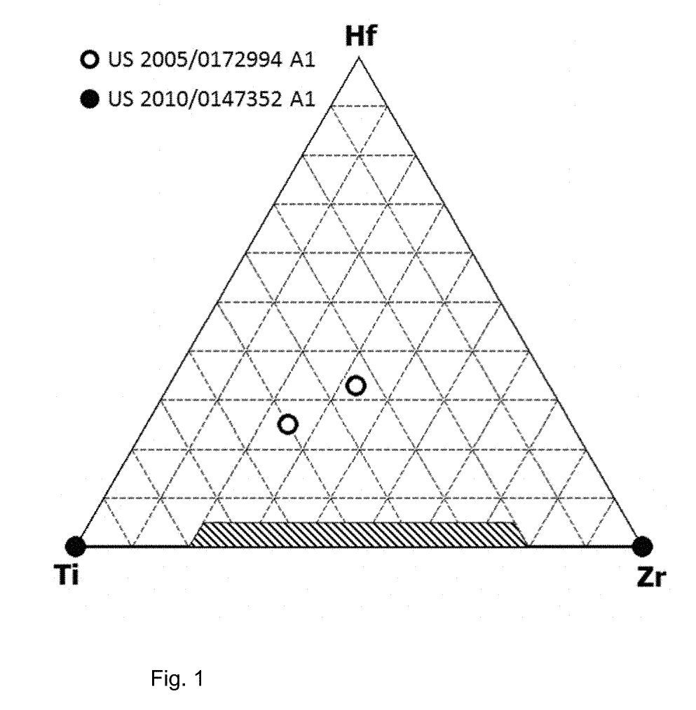

In the examples set out above, the overall composition comprises both elements Ti_{c}Zr_{1-c} in a ratio of 0.2≤c≤0.8 with only a small proportion of hafnium. The composition regions of the α lattice site examined in relation to A and B substitution in this work are shown as a shaded area in FIG. 1 by way of illustration. The compositions examined in relation to A and B substitution in the state of the art in publications US2005/0172994 A1 and US2010/0147352 A1 are illustrated by means of dots.

A series of test was carried out to examine the influence of substitution with A and B atoms in the system AₓB_{y}(Ti_{c}Zr_{1-c})_{1-x-y}NiSn in which x and y varied between 0.005≤x,y≤0.13. The target range for the composition on the α lattice site was set with c between 0.2≤c≤0.8. The elements Ti and Zr were partially replaced by small amounts of Hf, the proportion of Hf in Ti+Zr+Hf being less than 5 atom %.

It was established in the tests that, surprisingly, no pure half-Heusler compounds are obtained. The atoms from the groups A and B could not be detected detached in the half-Heusler phase, the detection limit in the energy-dispersive X-ray spectroscopy method of analysis chosen being approx. 0.2%. Instead A- and B-rich foreign phases formed even at small quantities of substitution atoms (x, y=0.005).

It was similarly surprising that good thermoelectric properties with high ZT values were measured at these half-Heusler compounds with integrated A- and B-rich phases. It is not therefore necessary to avoid the occurrence of foreign phases in order to obtain good thermoelectric materials.

In the half-Heusler compounds Ti_{c}Zr_{1-c}NiSn described here with 0.2≤c≤0.8, the solubility of the A and B atoms appears to be significantly reduced, so resulting in the foreign phases observed. This lack of solubility in the half-Heusler phase is surprising. It is also surprising that these foreign phases have an advantageous influence on thermoelectric properties.

### Example 1

Materials with the composition shown in Table 1 were produced. This was achieved by melting the materials in the composition given by means of vacuum induction melting. Due to the content of 2.7 mass % Hf as an accompanying element in the Zr used, 0.4 atom % of the Zr and Ti in the molten materials were replaced by Hf. The cast block was further processed by first homogenising it at 1000° C. in argon as a protective gas for 24 hours and then grinding it into a fine powder with a median particle size of less than 10 μm. The powder was then pressed into green bodies at a pressure of 2 t/cm2 in a tool press and finally sintered at 1100° C. to 1300° C. for 4 hours in a vacuum to form a dense body.

TABLE 1
Composition of materials according to Example 1 and
their Seebeck coefficients at room temperature

| | Composition in atom % | S (μV/K) @ RT |
|---|---|---|
| Example 1.1 | 4.2% La—4.2% Ta—16.7% | −38 |
| | Ti—8.3% Zr—33.3% Sn, rest Ni | |
| Example 1.2 | 4.2% Y—4.2% Ta—16.7% | −56 |
| | Ti—8.3% Zr—33.3% Sn, rest Ni | |
| Example 1.3 | 4.2% La—4.2% Nb—16.7% | −22 |
| | Ti—8.3% Zr—33.3% Sn, rest Ni | |
| Example 1.4 | 4.2% Y—4.2% Nb—16.7% | −41 |
| | Ti—8.3% Zr—33.3% Sn, rest Ni | |

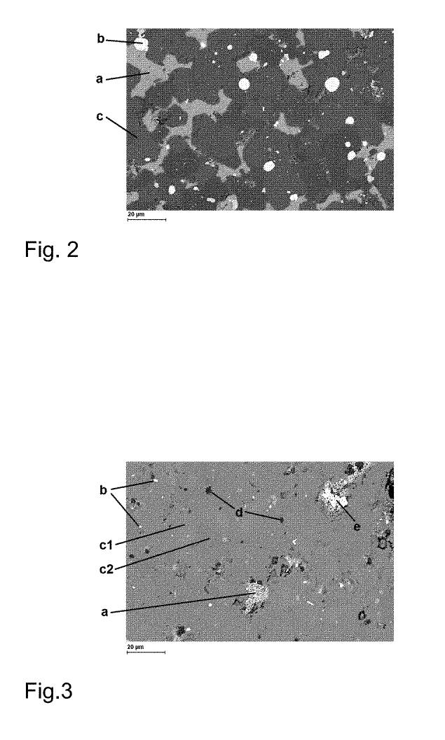

The microstructure of materials produced in this way was examined using scanning electron microscopy (SEM). FIG. 2 shows a scanning electron microscope image of the microstructure of the material from Example 1.1. In all the examples there is a main phase in the composition of a half-Heusler phase in the materials (phase c in FIG. 2) with the composition 16.4% Ti—16.9% Zr—33.3% Sn—rest Ni or ˜Ti_{0.5}Zr_{0.5}NiSn). Alongside the main phase there are two different auxiliary phases, which have a high concentration of one of the added elements from groups A and B (phases A and B in FIG. 2). In the main phase, by contrast, the added elements from groups A and B cannot be detected by means of energy-dispersive X-ray spectroscopy, the detection limit being approx. 0.2 atom %. Example 1 thus shows clearly that the expected solubility of element groups A and B in the αNiSn system are not achieved for mixed occupation of the α lattice site with Ti and Zr.

Rods with dimensions of 3 mm×3 mm×13 mm were sawed from the materials. The Seebeck coefficients of these samples were determined at room temperature and are also listed in Table 1. The maximum Seebeck coefficient was −56 μV/K for Example 1.2. The Seebeck coefficients of the materials from Example 1 were therefore too low to be useful for practical thermoelectric energy conversion. However, the proportion of A- and B-rich auxiliary phases in Example 1 is very high. The series of tests in Example 2 below was therefore devised to examine the influence of a lower proportion of these foreign phases on thermoelectric properties.

### Example 2

First, as a comparative example, a powder made of a material without elements from groups A and B was produced as in Example 1. The composition corresponds to a half-Heusler phase and is given in Table 2. Due to the content of 2.7 mass % Hf as an accompanying element in the Zr used a total of 0.7 atom % of the Zr and Ti is replaced by Hf. Further materials, their compositions also given in Table 2, were produced by mixing the powder from Example 1 with the powder from Example 2.1 in various ratios and by the subsequent pressing and sintering of the powder mixtures as in Example 1. The materials from Example 2 contain smaller proportions of elements from groups A and B than those from Example 1.

TABLE 2
Composition of materials according to Example 2

| | Composition in atom % |
|---|---|
| Comp. example 2.1 | 16.7% Ti—16.7% Zr—33.3% Sn, rest Ni |
| Example 2.2 | 0.17% La—0.17% Ta—16.7% Ti—16.3% |
| | Zr—33.3% Sn, rest Ni |
| Example 2.3 | 0.5% La—0.5% Ta—16.7% Ti—15.7% |
| | Zr—33.3% Sn, rest Ni |
| Example 2.4 | 0.8% La—0.8% Ta—16.7% Ti—15.0% |
| | Zr—33.3% Sn, rest Ni |
| Example 2.5 | 1.7% La—1.7% Ta—16.7% Ti—13.3% |
| | Zr—33.3% Sn, rest Ni |
| Example 2.6 | 0.5% Y—0.5% Ta—16.7% Ti—15.7% |
| | Zr—33.3% Sn, rest Ni |
| Example 2.7 | 0.8% Y—0.8% Ta—16.7% Ti—15.0% |
| | Zr—33.3% Sn, rest Ni |
| Example 2.8 | 0.5% La—0.5% Ta—16.7% Ti—15.7% |
| | Zr—33.3% Sn, rest Ni |
| Example 2.9 | 0.8% La—0.8% Nb—16.7% Ti—15.0% |
| | Zr—33.3% Sn, rest Ni |
| Example 2.10 | 0.5% Y—0.5% Nb—16.7% Ti—15.7% |
| | Zr—33.3% Sn, rest Ni |
| Example 2.11 | 0.8% Y—0.8% Nb—16.7% Ti—15.0% |
| | Zr—33.3% Sn, rest Ni |

The microstructure of the materials was examined by means of SEM. The microstructure of the material from Example 2.4 is shown in FIG. 3 by way of example. In all cases main phases in the form of half-Heusler phases (phases c and c2 in FIG. 3) and A- and B-rich auxiliary phases (phases a and b in FIG. 3) occur. In some cases it is also possible to observe pores in the microstructure due to incomplete sintering (d) or inclusions of an Ni—Sn phase (e).

The EDX analysis of the half-Heusler phases in FIG. 3 gave two different compositions: 12.9% Ti—21.4% Zr—34.0% Sn—rest Ni (c1) and 20.3% Ti—13.1% Zr—34.6% Sn—rest Ni (c2). In examples 2.2 to 2.11, too, no solubility of the elements from groups A and B was established above the detection limit of 0.2% in the half-Heusler phase.

Rods with dimensions of 3 mm×3 mm×13 mm were sawed from the materials. The Seebeck coefficients and electrical conductivity of these samples were measured. The results and the power factors calculated from them are listed in Table 3. As the table shows, the materials from Example 2 have a clearly higher Seebeck coefficient than the materials from Example 1. Furthermore, in all of examples 2.2 to 2.11, which possess a proportion of A- and B-rich foreign phases, the power factor is clearly higher than in the comparative Example 2.1, which consists of a half-Heusler phase without A- and B-rich foreign phases. Example 2 therefore demonstrates, contrary to expectations, that the presence of A- and B-rich foreign phases improves rather than diminishes thermoelectric properties.

TABLE 3
Thermoelectric properties of materials from
Example 2 at room temperature and 400° C.

| | RT | | | 400° C. | | |
|---|---|---|---|---|---|---|
| | S | σ | PF | S | σ | PF |
| | (μV/ | (S/ | (mWm⁻¹ | (μV/ | (S/ | (mWm⁻¹ |
| | K) | cm) | K⁻²) | K) | cm) | K⁻²) |
| Comp. | −248 | 198 | 1.2 | −241 | 478 | 2.8 |
| example 2.1 | | | | | | |
| Example 2.2 | −199 | 482 | 1.9 | −226 | 643 | 3.3 |
| Example 2.3 | −144 | 1061 | 2.2 | −203 | 890 | 3.7 |
| Example 2.4 | −123 | 1474 | 2.2 | −185 | 1140 | 3.9 |
| Example 2.5 | −85 | 2637 | 1.9 | −141 | 1866 | 3.7 |
| Example 2.6 | −143 | 1142 | 2.3 | −200 | 967 | 3.9 |
| Example 2.7 | −137 | 1211 | 2.3 | −196 | 1020 | 3.9 |
| Example 2.8 | −131 | 1196 | 2.1 | −185 | 1035 | 3.6 |
| Example 2.9 | −97 | 1954 | 1.8 | −154 | 1466 | 3.5 |
| Example 2.10 | −138 | 1111 | 2.1 | −192 | 976 | 3.6 |
| Example 2.11 | −112 | 1544 | 1.9 | −169 | 1203 | 3.4 |

### Example 3

In Example 3 the effect of A- and B-rich foreign phases for half-Heusler compounds are examined with a further composition range of the α lattice site. To this end, A- and B-free half-Heusler compounds with the composition 10.0% Ti—23.3% Zr—33.3% Sn—rest Ni (Ti_{0.4}Zr_{0.6}NiSn) and 23.3% Ti—10.0% Zr—33.3% Sn—rest Ni (Ti_{0.7}Zr_{0.3}NiSn) were melted as in Example 1. Due to the content of 2.7 mass % Hf as an accompanying element in the Zr used, in the compounds a total of 1%, 0.8% or 0.4% of the Zr and Ti are replaced by Hf. As in Example 2, the compounds were processed into a powder and then mixed in various ratios with the powders of the materials from Example 1. These were then made into dense test pieces with the compositions listed in Table 4 by means of sintering.

TABLE 4
Composition of materials according to Example 3

| | Composition in atom % |
|---|---|
| Example 3.1 | 0.3% La—0.3% Ta—10.5% Ti—22.1% |
| | Zr—33.3% Sn, rest Ni |
| Example 3.2 | 0.8% La—0.8% Ta—11.3% Ti—20.3% |
| | Zr—33.3% Sn, rest Ni |
| Example 3.3 | 0.3% La—0.3% Ta—13.6% Ti—19.1% |
| | Zr—33.3% Sn, rest Ni |
| Example 3.4 | 0.8% La—0.8% Ta—14.0% Ti—17.7% |
| | Zr—33.3% Sn, rest Ni |
| Example 3.5 | 0.8% Y—0.8% Ta—11.3% Ti—20.3% |
| | Zr—33.3% Sn, rest Ni |
| Example 3.6 | 0.8% Y—0.8% Ta—22.0% Ti—10.0% |
| | Zr—33.3% Sn, rest Ni |

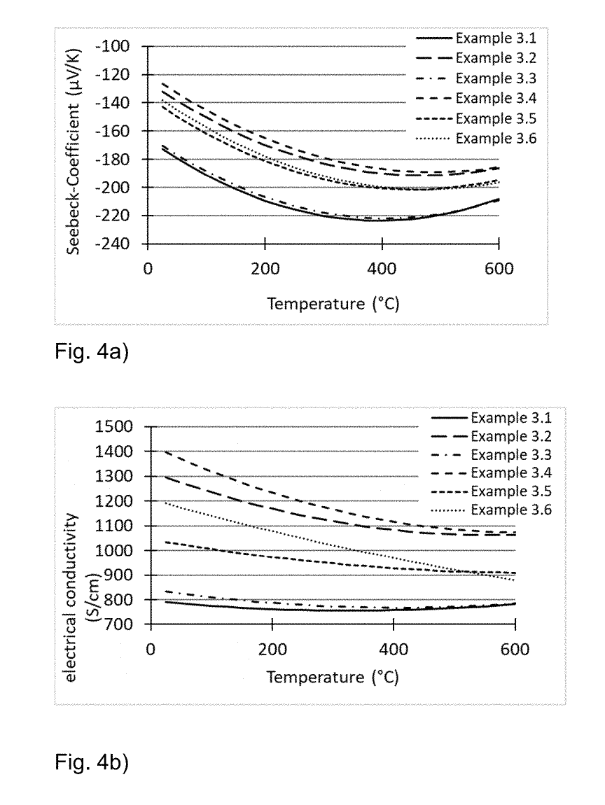

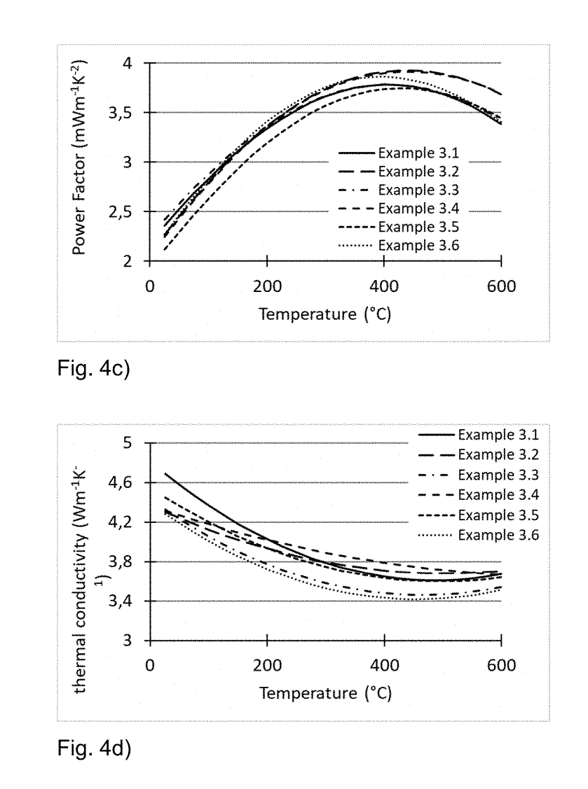

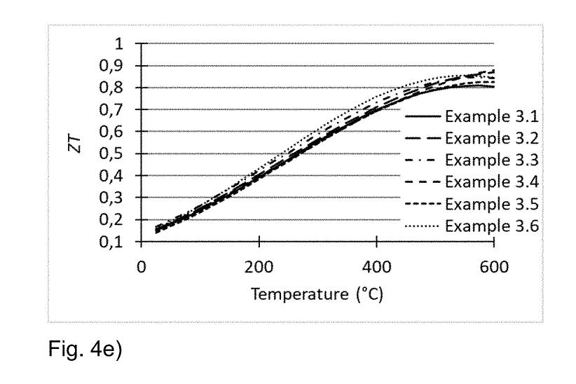

Rods with dimensions of 3 mm×3 mm×13 mm were sawed from the materials to measure Seebeck coefficients and electrical conductivity. Samples with dimensions of 10 mm×10 mm×1 mm were also produced to measure heat conductivity using the laser flash method. The temperature-dependent thermoelectric properties measured for the materials in this way are shown in FIG. 4.

FIG. 4a shows a graph of Seebeck coefficient dependent on temperature. FIG. 4b shows a graph of electrical conductivity dependent on temperature. FIG. 4c shows a graph of power factor dependent on temperature. FIG. 4d shows a graph of heat conductivity dependent on temperature. FIG. 4e shows a graph of figure of merit ZT dependent on temperature.

All the materials from Example 3 present a high Seebeck coefficient. Alongside the electrical conductivity measured, there are also high power factors comparable with the materials from Example 2. Example 3 therefore shows that the A- and B-rich foreign phases also have an advantageous effect on thermoelectric properties in the extended composition range of the α lattice site.

This is confirmed by the measurement of heat conductivity. As shown in FIG. 4e, in all cases the combination of the measured properties gives a high ZT value, the maximum ZT value occurring in a temperature range of between 500° C. and 600° C. and lying between 0.8≤ZTₘₐₓ≤0.9.

### Example 4

The materials used in the preceding examples each contain elements from both groups A and B together. No solubility of these elements was observed in the half-Heusler phase. In Example 4 it is demonstrated that when only one element from one of groups A and B are added there is no solubility of this element in the half-Heusler phase. To ascertain this the compositions listed in Table 5 were melted using vacuum induction melting and processed as described in Example 1.

TABLE 5
Composition of materials according to Example 4

| | Composition in atom % |
|---|---|
| Example 4.1 | 0.8% La—16.7% Ti—15.8% |
| | Zr—33.3% Sn - rest Ni |
| Example 4.2 | 0.8% Ta—16.7% Ti—15.8% |
| | Zr—33.3% Sn- rest Ni |

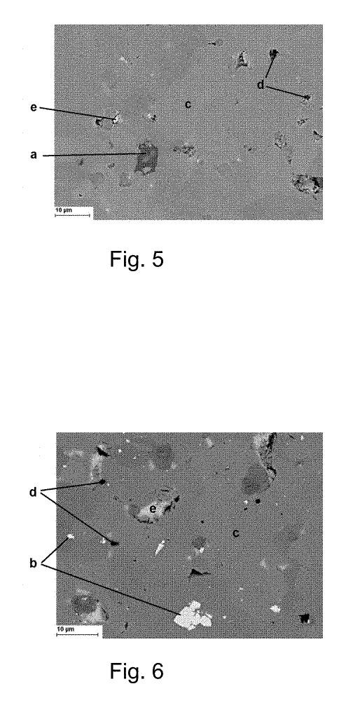

The materials produced in this way were analysed using SEM. The microstructures of the materials from Example 4 are shown in FIGS. 5 and 6. In both cases, the main component of the structure is a half-Heusler phase (phase c in FIGS. 5 and 6) of composition 16% Ti—18% Zr—34% Sn—rest Ni. In this phase the elements La and Ta cannot be detected using EDX. In contrast, however, the structure also includes La-rich auxiliary phases (phase a in FIG. 5) or Ta-rich auxiliary phases (phase b in FIG. 6). The results of the SEM examination therefore demonstrate that even in the presence of only one element from groups A and B it is not detached in the half-Heusler phase.

### Example 5

In Example 5 the thermoelectric properties of materials with Ti-rich auxiliary phases are compared with the thermoelectric properties of conventional half-Heusler compounds in which the tin lattice site has been antimony-doped. To this end the compositions listed in Table 6 were melted by vacuum induction melting and processed as described in Example 1. In addition to the processing described in Example 1, the materials were annealed for 48 hours at 930° C. in a protective gas (argon) prior to characterisation.

TABLE 6
Composition of materials according to Example 5

| | Composition in atom % |
|---|---|
| Example 5.1 | 0.3% Ta—16.7% Ti—16.3% |
| | Zr—33.3% Sn - rest Ni |
| Example 5.2 | 0.8% Ta—16.7% Ti—15.8% |
| | Zr—33.3% Sn- rest Ni |
| Comp. example 5.3 | 16.7% Ti—16.7% Zr—33.0% |
| | Sn—0.3% Sb - rest Ni |
| Comp. example 5.4 | 16.7% Ti—16.7% Zr—32.7% |
| | Sn—0.7% Sb - rest Ni |

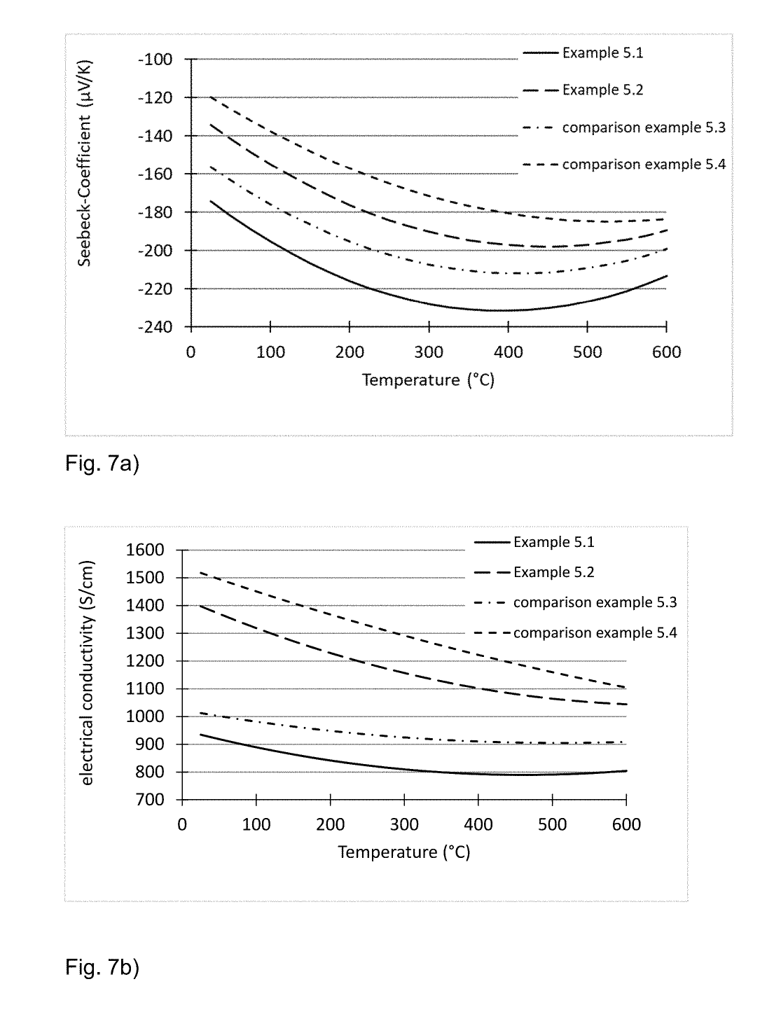

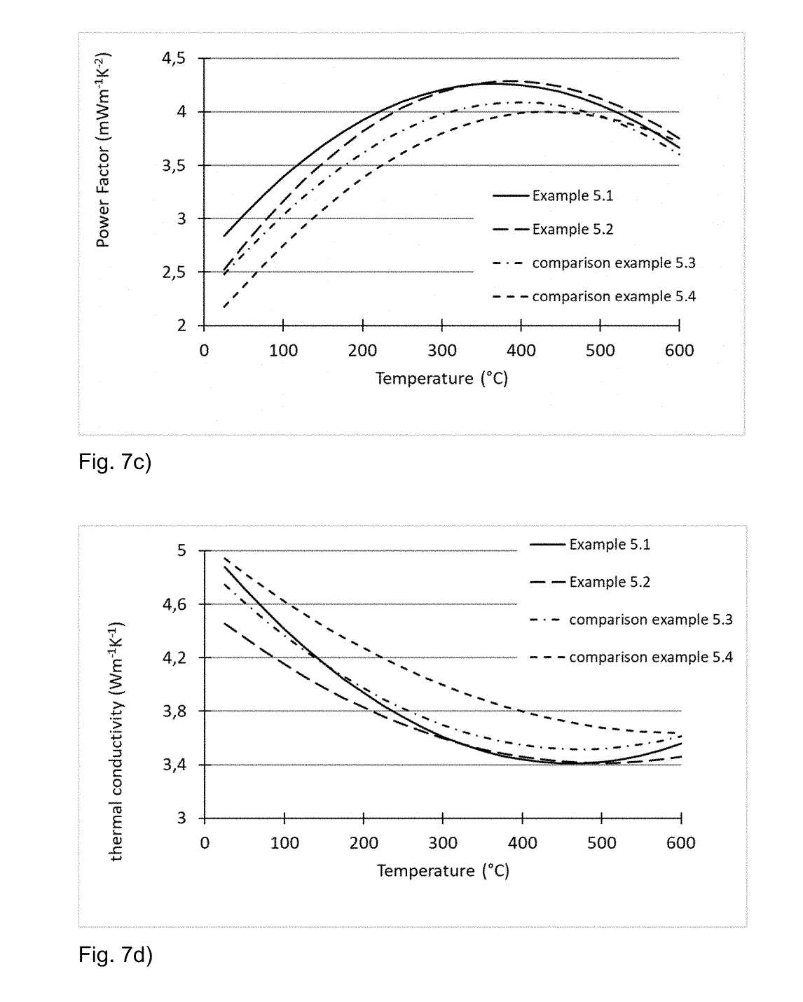

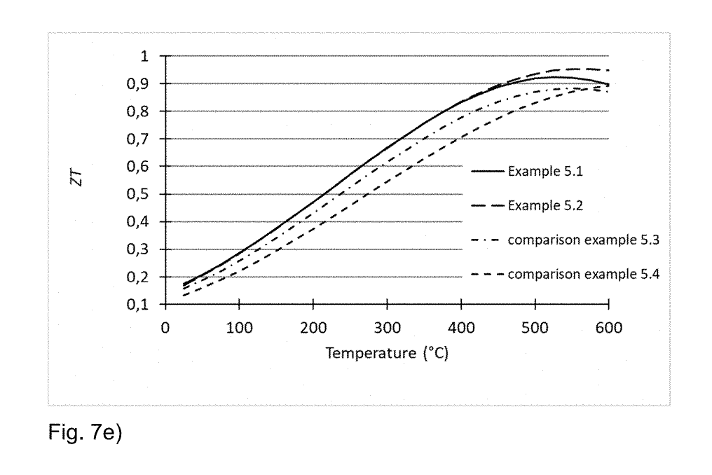

Rods with dimensions of 2.5 mm×2.5 mm×13 mm were sawed from the materials to measure Seebeck coefficients and electrical conductivity, and samples with dimensions of 10 mm×10 mm×1 mm were taken to measure heat conductivity using the laser flash method. The temperature-dependent thermoelectric properties measured for the materials in this way are shown in FIG. 7.

FIG. 7a shows a graph of Seebeck coefficients dependent on temperature. FIG. 7b shows a graph of electrical conductivity dependent on temperature. FIG. 7c shows a graph of power factor dependent on temperature. FIG. 7d shows a graph of heat conductivity dependent on temperature. FIG. 7e shows a graph of figure of merit ZT dependent on temperature.

A comparison of the data shows that the materials from Examples 5.1 and 5.2 cover similar ranges for Seebeck coefficient and electrical conductivity as the materials in the comparative examples 5.3 and 5.4. The power factors and ZT values, however, are clearly higher in the materials from Examples 5.1 and 5.2. These materials, which correspond to this invention and contain Ta-rich auxiliary phases, reach maximum ZT values of between 0.9≤ZTₘₐₓ≤1.0 in the temperature range 500° C. to 600° C. In the same temperature range, by contrast, materials from conventionally doped half-Heusler compounds without Ta-rich foreign phases reach only maximum ZT values of less than 0.9.

### Example 6

In Example 6 the thermoelectric properties of materials which possess A-rich and/or B-rich auxiliary phases in combination with an antimony-doped half-Heusler compound are examined. To this end, the compositions listed in Table 7 were melted, processed in the manner described in Example 1 and then annealed for 48 hours at 930° C. in a protective gas (argon).

TABLE 7
Composition of materials according to Example 6

| | Composition in atom % |
|---|---|
| Example 6.1 | 0.4% Ta—16.7% Ti—16.3% Zr—33.2% |
| | Sn—0.2% Sb - rest Ni |
| Example 6.2 | 0.4% Ta—16.7% Ti—16.3% Zr—33.0% |
| | Sn—0.3% Sb - rest Ni |
| Example 6.3 | 0.4% La—0.4% Ta—16.7% Ti—15.8% |
| | Zr—33.0% Sn—0.3% Sb - rest Ni |
| Example 6.4 | 0.6% Ta—16.7% Ti—15.8% Zr—1.5% |
| | Hf—33.2% Sn—0.2% Sb - rest Ni |

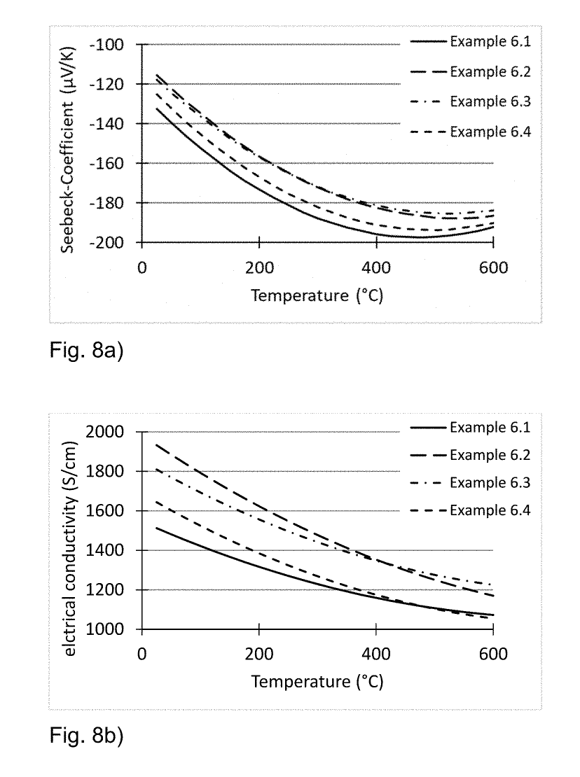

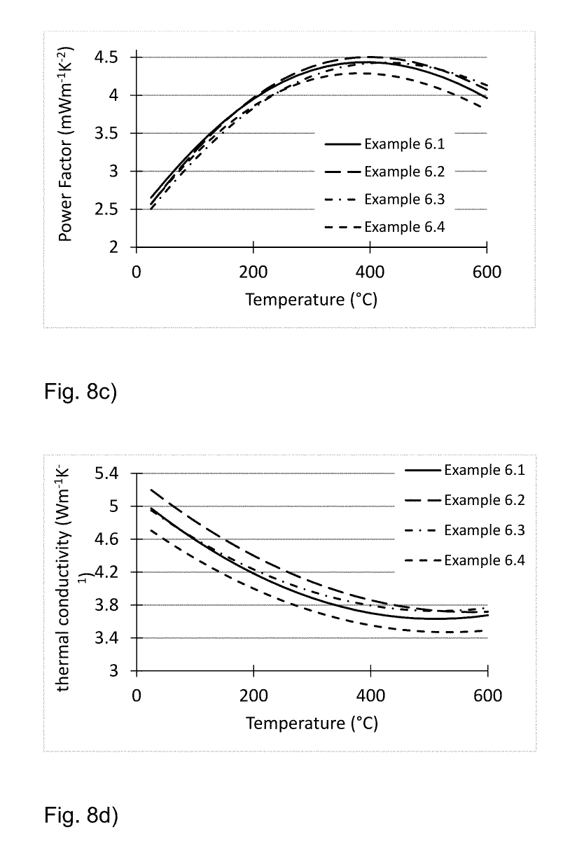

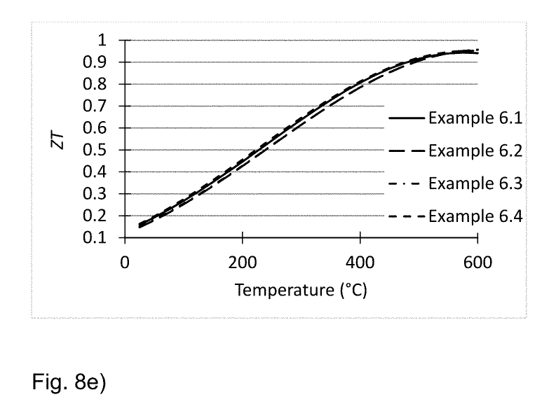

The measurement samples prepared from the materials for thermoelectric characterisation were produced as described in Example 5. The thermoelectric properties measured are shown in FIG. 8.

FIG. 8a shows a graph of Seebeck coefficients dependent on temperature. FIG. 8b shows a graph of electrical conductivity dependent on temperature. FIG. 8c shows a graph of the power factor dependent on temperature. FIG. 8d shows a graph of heat conductivity dependent on temperature. FIG. 8a shows a graph of figure of merit ZT dependent on temperature.

The materials from Example 6 all achieve very good thermoelectric properties with high power factors and a maximum ZT value in a temperature range of between 500° C. and 600° C. of 0.9≤ZTₘₐₓ≤1.0. In particular, the power factors and ZT values achieved are higher than in the comparative Examples 5.3 and 5.4, which represent antimony-doped half-Heusler compounds without A- and/or B-rich auxiliary phases.

It is therefore possible with this invention to produce higher-performance, low-Hf, thermoelectric materials based on αNiSn half-Heusler compounds. These materials have a multi-phase composite structure in which inclusions from A-rich and/or B phases are embedded in a matrix with one or more phases with a half-Heusler structure, the phases with the half-Heusler structure comprising at least 6 atom % Ti and 6 atom % Zr.

### Key to FIG. 4

Seebeck coefficient (μV/K)

### Temperature (° C.)

### Example 3.1 etc.

Electrical conductivity (S/cm)

### Temperature (° C.)

### Example 3.1 etc.

Power factor (mWm⁻¹K⁻²)

### Temperature (° C.)

### Example 3.1 etc.

Heat conductivity (mWm⁻¹K⁻¹)

### Temperature (° C.)

### Example 3.1 etc.

### ZT

### Temperature (° C.)

### Example 3.1 etc.

### Key to FIG. 7

Seebeck coefficient (μV/K)

### Temperature (° C.)

### Example 5.1 etc.

Comp. example 5.3 etc.
Electrical conductivity (S/cm)

### Temperature (° C.)

### Example 5.1 etc.

Comp. example 5.3 etc.
Power factor (mWm⁻¹K⁻²)

### Temperature (° C.)

### Example 3.1 etc.

Comp. example 5.3 etc.
Heat conductivity (mWm⁻¹K⁻¹)

### Temperature (° C.)

### Example 3.1 etc.

Comp. example 5.3 etc.

### ZT

### Temperature (° C.)

### Example 3.1 etc.

Comp. example 5.3 etc.

### Key to FIG. 8

Seebeck coefficient (μV/K)

### Temperature (° C.)

### Example 6.1 etc.

Electrical conductivity (S/cm)

### Temperature (° C.)

### Example 6.1 etc.

Power factor (mWm⁻¹K⁻²)

### Temperature (° C.)

### Example 6.1 etc.

Heat conductivity (mWm⁻¹K⁻¹)

### Temperature (° C.)

### Example 6.1 etc.

### ZT

### Temperature (° C.)

### Example 6.1 etc.

1. A thermoelectric article for a thermoelectric conversion device having an overall composition consisting essentially of
6 atom %≤Ti≤27 atom %,
6 atom %≤Zr≤27 atom %,
0 atom %≤Hf≤1.7 atom %,
where 28 atom %≤(Ti+Zr+Hf)≤38 atom %;
28 atom %≤Sn≤38 atom %,
0 atom %≤Sb≤3 atom %,
where 28 atom %≤(Sn+Sb)≤38 atom %;
0 atom %≤A≤7 atom %,
0 atom %≤B≤7 atom %, where A is one or more of the elements selected from the group consisting of Sc, Y and La, B is one or more of the elements selected from the group consisting of V, Nb and Ta and 0.15 atom %≤A+B≤7 atom %;
the rest being Ni and up to 5 atom % impurities.

2. A thermoelectric article according to claim 1, wherein the thermoelectric article comprises at least one phase with a half-Heusler structure.

3. A thermoelectric article according to claim 2, wherein the phase with the half-Heusler structure comprises less than 0.2 atom % of one or more of the elements A and B.

4. A thermoelectric article according to claim 2, wherein the composition of the phases with the half-Heusler structure is defined by the chemical formula TiₐZr₁₋ₐNiSn_{1-b}Sb_{b}, where 0≤a≤1 and 0≤b≤0.1.

5. A thermoelectric article according to claim 1, wherein the thermoelectric article comprises one or more A-rich phases without a half-Heusler structure and one or more B-rich phases without a half-Heusler structure.

6. A thermoelectric article according to claim 1, wherein the overall composition is AₓB_{y}Tiₐ₁Zrₐ₂Hfₐ₃NiSn_{c}Sb_{b}, where
0≤x≤0.2, 0≤y≤0.2, 0.005≤(x+y)≤0.2,
0.2≤a1≤0.8, 0.2≤a2≤0.8, 0≤a3≤0.05, 0.9≤(a1+a2+a3)≤1.1,
0≤b≤0.1 and
0.9≤(b+c)≤1.1.

7. A thermoelectric article according to claim 6, wherein x=y.

8. A thermoelectric article according to claim 1, the thermoelectric article having a maximum thermoelectric figure of merit ZTₘₐₓ of ≥0.8.

9. A thermoelectric article according to claim 1, the thermoelectric article having a thermoelectric figure of merit ZTₘₐₓ of ZTₘₐₓ≥0.8, where 400° C.≤Tₘₐₓ≤700° C.

10. A thermoelectric article according to claim 1, the thermoelectric article having a Seebeck coefficient S where −350≤S≤−80 (μV/K).

11. A thermoelectric article according to claim 1, the thermoelectric article having a maximum power factor PFₘₐₓ of >3.5 (mW m⁻¹ K⁻²).

12. A composite material for a thermoelectric conversion device comprising:
a matrix with at least one phase with a αNiβ-based half-Heusler structure, α being at least one of the elements in a group consisting of Ti, Zr and Hf and β being at least one of the elements in the group consisting of Sn and Sb, where the proportion of Hf is less than 1.7 atom %,
inclusions from an A-rich phase, A being one or more of the elements selected from the group consisting of Sc, Y and La, and
inclusions from a B-rich phase, B being one or more of the elements selected from the group consisting of V, Nb and Ta, and
a maximum thermoelectric figure of merit ZTₘₐₓ of ≥0.8.

13. A composite material according to claim 12, wherein the composition of the phases with the half-Heusler structure is defined by the chemical formula TiₐZr₁₋ₐNiSn_{1-b}Sb_{b}, where 0≤a≤1 and 0≤b≤0.1.

14. A composite material according to claim 12, wherein the matrix comprises less than 0.2 atom % of one or more of the elements A and B.

15. A composite material according to claim 12, wherein the inclusions from an A-rich phase and the inclusions from a B-rich phase do not have a half-Heusler structure.

16. A composite material according to claim 12, wherein the composite material comprises up to 10 vol % of the A-rich phase and the B-rich phase.

17. A composite material according to claim 12, the composite material having an overall composition consisting essentially of
6 atom %≤Ti≤27 atom %,
6 atom %≤Zr≤27 atom %,
0 atom %≤Hf≤1.7 atom %,
where 28 atom %≤(Ti+Zr+Hf)≤38 atom %;
28 atom %≤Sn≤38 atom %,
0 atom %≤Sb≤3 atom %,
where 28 atom %≤(Sn+Sb)≤38 atom %;
0 atom %≤A≤7 atom %,
0 atom %≤B≤7 atom %, where A is one or more of the elements chosen from the group consisting of Sc, Y and La, B is one or more of the elements selected from the group consisting of V, Nb and Ta and 0.15 atom %≤A+B≤7 atom %;
the rest being Ni and up to 5 atom % impurities.

18. A composite material according to claim 12, the composite material having a maximum thermoelectric figure of merit ZTₘₐₓ where ZTₘₐₓ≥0.8 and 400° C.≤Tₘₐₓ≤700° C.

19. A composite material according to claim 12, the composite material having a maximum power factor PFₘₐₓ of >3.5 (mW m⁻¹ K⁻²).

20. A thermoelectric module having at least one thermoelectric element made of a composite material according to claim 12.

21. A process for producing a thermoelectric article for a thermoelectric conversion device, the process comprising:
providing a starting material consisting essentially of
6 atom %≤Ti≤27 atom %,
6 atom %≤Zr≤27 atom %,
0 atom %≤Hf≤1.7 atom %, where 28 atom %≤(Ti+Zr+Hf)≤38 atom %;
28 atom %≤Sn≤38 atom %,
0 atom %≤Sb≤3 atom %, where 28 atom %≤(Sn+Sb)≤38 atom %;
0 atom %≤A≤7 atom %,
0 atom %≤B≤7 atom %, where A is one or more of the elements chosen from the group consisting of Sc, Y and La, B is one or more of the elements selected from the group consisting of V, Nb and Ta and 0.15 atom %≤A+B≤7 atom %;
the rest being Ni and up to 5 atom % impurities,
melting and subsequently hardening the starting material to form at least one block,
homogenising the block at a temperature of 900° C. to 1200° C. for a length of time t, where 0.5 h≤t≤100 h, to form a homogenised block,
crushing the homogenised block,
grinding the reduced block, a powder thereby being formed,
cold pressing the powder, a green body thereby being formed,
sintering the green body at a maximum pressure of 1 MPa at a temperature of 1000° C. to 1500° C. for 0.5 h to 24 h, thereby producing a thermoelectric article.

22. A process according to claim 21, further comprising casting the molten starting material into a block.

23. A process according to claim 21, wherein the block is reduced to small pieces by means of a jaw crusher.

24. A process according to claim 21, the crushing is performed by use of a disc mill or a roller mill.

25. A process according to claim 21, wherein the block is reduced to a coarse powder, the coarse powder then being ground to a fine powder in a further grinding process and the fine powder being cold pressed.

26. A process according to claim 25, wherein the further grinding process is carried out by means of a planetary ball mill or a jet mill.

27. A process according to claim 21, wherein the starting material is melted by vacuum induction melting.

28. A process according to claim 21, wherein the block is homogenised in argon or in a vacuum.

29. A process according to claim 21, wherein the block is homogenised at a temperature of 1050° C. to 1180° C. for a length of time t, where 16 h≤t≤36 h.

30. A process for producing a thermoelectric article comprising the following:
providing a first powder comprising essentially 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, 28 atom %≤(Sn+Sb)≤38 atom %; the rest being Ni and up to 5 atom % impurities, the proportion of elements from groups A and B being less than 0.2 atom %,
providing a second powder comprising 0 atom %≤A≤7 atom % and/or 0 atom %≤B≤7 atom %, where A is one or more of the elements chosen from the group consisting of Sc, Y and La, B is one or more of the elements selected from the group consisting of V, Nb and Ta and 0.15 atom %≤A+B≤7 atom %,
mixing the first powder and the second powder, thereby producing a starting powder,
cold pressing the starting powder, thereby forming a green body,
sintering the green body at a maximum pressure of 1 MPa at a temperature of 1000° C. to 1500° C. for 0.5 h to 24 h, thereby producing a thermoelectric article.

31. A process according to claim 30, wherein the green body is sintered in a protective gas or a vacuum.

32. A process according to claim 30, wherein the thermoelectric article is processed into a plurality of working components by means of sawing and/or grinding processes.

33. A process according to claim 30, the second powder further comprising 6 atom %≤Ti≤27 atom %, 6 atom %≤Zr≤27 atom %, 0 atom %≤Hf≤1.7 atom %, where 28 atom %≤(Ti+Zr+Hf)≤38 atom %; 28 atom %≤Sn≤38 atom %, 0 atom %≤Sb≤3 atom %, where 28 atom %≤(Sn+Sb)≤38 atom %; the rest being Ni and up to 5 atom % impurities.
